(19) United States
(12) Patent Application Publication
(10) Pub. No.: US 2025/0223514 A1
(43) Pub. Date: Jul. 10, 2025

(54) CLEANSING COMPOSITION FOR WAFER DICING

(71) Applicant: SAMSUNG ELECTRONICS CO., LTD., SUWON-SI (KR)

(72) Inventor: Inyeol YUN, Suwon-si (KR)

(21) Appl. No.: 19/004,901

(22) Filed: Dec. 30, 2024

(30) Foreign Application Priority Data
Jan. 8, 2024 (KR) 10-2024-0003110

(51) Int. Cl. C11D 1/72; C11D 3/22; C11D 3/43

(52) U.S. Cl. CPC C11D 1/721; C11D 3/221; C11D 3/43

(57) ABSTRACT

A cleansing composition for wafer dicing includes a surfactant that contains a hydrophilic moiety and a hydrophobic moiety, and a solvent. The hydrophilic moiety is selected from monosaccharides, disaccharides, or derivatives thereof. The hydrophobic moiety includes a C4 to C20 polyethylene glycol group substituted with an alkyl benzyl group.

### CROSS-REFERENCES TO RELATED APPLICATION

This application claims priority under 35 U.S.C. § 119 to Korean Patent Application No. 10-2024-0003110, filed on Jan. 8, 2024 in the Korean Intellectual Property Office, the disclosure of which is incorporated by reference in its entirety herein.

### 1. TECHNICAL FIELD

The present inventive concept relates to a cleansing composition for wafer dicing, and more particularly, to a cleansing composition for wafer dicing, including a surfactant.

### 2. DISCUSSION OF RELATED ART

In a process of manufacturing a semiconductor chip, a disk-shaped semiconductor wafer is divided into a plurality of regions by scribe lanes arranged in a grid. An element such as an integrated circuit or a system large-scale integration is formed in the divided region. Thereafter, a wafer dicing process, in which the semiconductor wafer is cut along the scribe lanes, is performed. The regions divided by the scribe lanes may then be separated to form a plurality of dies.

Silicon particles, which are scattered when the wafer is cut by a blade during the wafer dicing process, are adsorbed on a top surface of the wafer or on a pad, resulting in a decrease in yield for the manufacturing process. A cleanser for wafer dicing may be used to prevent these problems.

### SUMMARY

An embodiment of the present inventive concept provides a cleansing composition for wafer dicing that does not leave a residue on a wafer surface. Therefore, the adsorption of silicon particles may be prevented and the cleansing composition has an increased cleansing ability for organic contaminants.

Also, aspects of embodiments of the present inventive concept are not limited to the above-described aspects, and other benefits of embodiments of the present inventive concept may be clearly understood by those skilled in the art from the following descriptions.

According to an embodiment of the present inventive concept, a cleansing composition for wafer dicing includes a surfactant that includes a hydrophilic moiety and a hydrophobic moiety, and a solvent. The hydrophilic moiety is selected from monosaccharides, disaccharides, or derivatives thereof, and the hydrophobic moiety includes a C4 to C20 polyethylene glycol group, which is substituted with an alkyl benzyl group.

According to an embodiment of the present inventive concept, a cleansing composition for wafer dicing includes a surfactant represented by Formula 1 below; and a solvent. In Formula 1, X is a monosaccharide, a disaccharide, or a derivative thereof, R¹ is a C4 to C20 polyether group substituted with an alkyl benzyl group, and Y¹ is a non-ionic hydrophilic group.

R¹—X—Y¹ <Formula 1>

According to an embodiment of the present inventive concept, a cleansing composition for wafer dicing includes a surfactant represented by Formula 5 below, and water. In Formula 5, n may be 1 or 2, and R⁷ and R⁸ are each independently a C6 to C12 polypropylene glycol group substituted with an alkyl benzyl group.

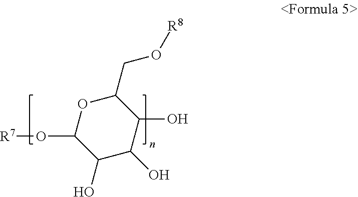

### DETAILED DESCRIPTION OF EMBODIMENTS

Unless otherwise defined, all terms used herein including technical and scientific terms have the same meaning as commonly understood by those skilled in the art to which the present inventive concept pertains. In addition, commonly used terms, as defined in dictionaries, should be interpreted to have meanings consistent with what they mean in the context of the relevant technology, and will be understood that the terms should not be interpreted in an overly formal sense unless explicitly defined herein.

A cleansing composition for wafer dicing according to an embodiment of the present inventive concept includes a surfactant including a hydrophilic moiety and a hydrophobic moiety, and a solvent.

According to an embodiment, the surfactant may include one hydrophilic moiety and at least one hydrophobic moiety connected to the hydrophilic moiety. For example, in an embodiment, in a chemical structure, the surfactant may include a head composed of the hydrophilic moiety and at least one leg connected to the head. The at least one leg may constitute the hydrophobic moiety of the surfactant.

According to an embodiment, the hydrophilic moiety may be selected from monosaccharides, disaccharides, or derivatives thereof. In some embodiments, the monosaccharide constituting the hydrophilic moiety in the surfactant may be a cyclic monosaccharide. For example, in an embodiment the monosaccharides may include a five-membered furanose ring or a six-membered pyranose ring. In some embodiments, the monosaccharides may include: pentose including ribose, arabinose, xylose, and lyxsose; hexose including allose, altrose, glucose, mannose, glucose, mannose, gulose, idose, galactose and talose; and isomers thereof.

In some embodiments, the disaccharides may be a compound in which two homologous monosaccharides or two heterogeneous monosaccharides, selected from the above-described monosaccharides, are linked to each other via a glycosidic bond.

In some embodiments, the hydrophilic moiety may include monosaccharide derivatives and disaccharide derivatives. In some embodiments, the monosaccharide derivatives and disaccharide derivatives may include derivatives in which at least one hydrogen atom and/or hydroxyl group is substituted with a hydrophilic group that is not a hydroxyl group. For example, the hydrophilic moiety of the surfactant may include a monosaccharide substituted with a hydrophilic group, or a disaccharide substituted with a hydrophobic group. In some embodiments, the hydrophilic group may include at least one non-ionic hydrophilic group selected from an amine oxide group, a phosphine oxide group, and a sulfur oxide group.

According to an embodiment, the hydrophobic moiety may include a main chain composed of a C4-C20 polyether and a hydrophobic group connected to an end of the main chain.

In some embodiments, polyether may include two or more copolymers selected from polyethylene glycol, polypropylene glycol, polybutylene glycol, ethylene glycol, propylene glycol, and butylene glycol. In some embodiments, the hydrophobic moiety may include a C4-C20 polyethylene glycol group having the end substituted with a hydrophobic group. Since the hydrophobic moiety according to an embodiment includes a main chain having an ether group, even when the chain is relatively long, a decrease in cleansing power of a surfactant by aggregation of other adjacent hydrophobic moieties due to excessively strengthened hydrophobicity may be prevented, and dispersibility in a solvent may be increased.

In some embodiments, the main chain of the hydrophobic moiety may be composed of C6 to C12 polyether. In a comparative embodiment in which a number of carbons of the main chain is less than the above-described range, hydrophobicity in the surfactant excessively decreases, and thus the surfactant may have reduced cleansing ability. In a comparative embodiment in which the number of carbons of the main chain is more than the above-described range, a length of the chain excessively increases, thus the hydrophobic moiety may be self-aggregated or may be aggregated with another adjacent hydrophobic moiety, which may cause a decrease in the cleansing ability of the surfactant.

In some embodiments, the hydrophobic group may include a benzyl group in which a hydrogen atom of a benzene ring is substituted with a C1 to C4 alkyl group. In some embodiments, an alkyl group may include a C1 and C2 linear chain alkyl group, and a C3 and C4 branched chain alkyl group. In some embodiments, the hydrophobic group is connected to the end of the main chain but includes a relatively short linear chain alkyl group or includes a relatively large-scale three-dimensional branched chain alkyl group, and thus a random coil and a self-aggregation of the hydrophobic moiety may be prevented.

In some embodiments, the hydrophobic group may include a benzyl group in which at least one among hydrogen atoms is substituted with one selected from a methyl group, an ethyl group, an isopropyl group, and a tert-butyl group. For example, in some embodiments the hydrophobic group may include a benzyl group substituted with an isopropyl group and/or a tert-butyl group.

In some embodiments, the surfactant may include two or more hydrophobic moieties. In some embodiments, the hydrophobic moiety may include a C4-C20 polyethylene glycol group, substituted with an alkyl benzyl group. In some embodiments, in the alkyl benzyl group, a hydrogen atom of a benzene ring may be substituted with an isopropyl group or a tert-butyl group.

According to an embodiment, the surfactant may be represented by Formula 1 below.

R¹—X—Y¹ <Formula 1>

In Formula 1, X may be a structure unit including at least one selected from a structural unit of Formula 2 below and a structural unit of Formula 3 below.

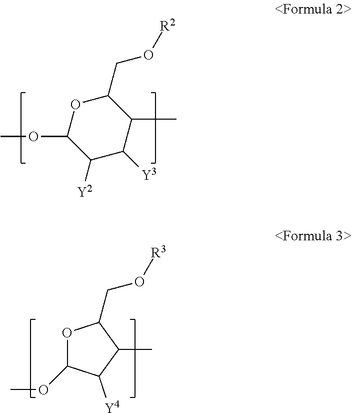

According to an embodiment, X in Formula 1 includes one or two structural units in Formula 2, includes one or two structural units in Formula 3, or includes one structural unit in Formula 2 and one structural unit in Formula 2. In some embodiments, when X in Formula 1 includes two of the structural unit in Formula 2 and/or the structural unit in Formula 3, the two structural units may be linked to each other by a glycosidic bond.

According to an embodiment, the 6-membered ring structure in Formula 2 and the 5-membered ring structure in Formula 3 may be the above-described hydrophobic moieties and may constitute a hydrophilic head of the surfactant. According to an embodiment, Y¹ in Formula 1, Y² and Y³ in Formula 2, and Y⁴ in Formula 3 may be each independently a hydrophilic group. In some embodiments, the head of the hydrophilic moiety may be composed of a non-ionic hydrophilic group. In some embodiments, Y¹ in Formula 1, Y² and Y³ in Formula 2, and Y⁴ in Formula 3 may be each a hydroxy group, an amine oxide group, a phosphine oxide group, or a sulfur oxide group.

In some embodiments, Y¹ in Formula 1, Y² and Y³ in Formula 2, and Y⁴ in Formula 3 may be the same hydrophilic group. In some other embodiments, at least some selected from Y¹ in Formula 1, Y² and Y³ in Formula 2, and Y⁴ in Formula 3 may be hydrophilic groups that are different from others of Y¹ to Y⁴.

According to an embodiment, at least one among R¹ in Formula 1, R² in Formula 2, and R³ in Formula 3 may be the above-described hydrophobic moiety of the surfactant and may constitute a hydrophobic leg of the surfactant. In some embodiments, R¹ in Formula 1, R² in Formula 2, and R³ in Formula 3 may be each independently hydrogen or a C4 to C20 polyethylene glycol group, substituted with an alkyl benzyl group, but at least one among R¹, R², and R³ may be the C4 to C20 polyethylene glycol group, substituted with an alkyl benzyl group.

In some embodiments, R¹ in Formula 1, R² in Formula 2, and R³ in Formula 3 may be each independently hydrogen, a triethylene glycol group substituted with an alkyl benzyl group, a tetraethylene glycol group substituted with an alkyl benzyl group, a pentaethylene glycol group substituted with an alkyl benzyl group, or a hexaethylene glycol group substituted with an alkyl benzyl group. However, at least one among R¹ in Formula 1, R² in Formula 2, and R³ in Formula 3 may include, as a hydrophobic moiety, the above-described polyethylene glycol group.

In some embodiments, the alkyl benzyl group may be a benzyl group in which a hydrogen atom of a benzene ring is substituted with a C1 to C4 alkyl group, wherein the alkyl group of the alkyl benzyl group may be linked to (e.g., bonded to) carbon at a para position of toluene and/or carbon at a meta position of toluene. In some embodiments, a C1 to C4 alkyl group may include a C1 and C2 linear chain alkyl group, and a C3 and C4 branched chain alkyl group. For example, in an embodiment the alkyl benzyl group may be a benzyl group substituted with at least one compound selected from a methyl group, an ethyl group, an isopropyl group, and a tert-butyl group. In some embodiments, the number of carbons constituting a polyethylene glycol group may be 6 to 12. In the above-described range, self-aggregation, or aggregation with a hydrophobic leg of another adjacent surfactant may decrease while increased adsorption capacity of the hydrophobic leg for an organic contaminant may be achieved.

In some embodiments, R¹ in Formula 1, R² in Formula 2, and R³ in Formula 3 may be the same hydrophobic group. In some other embodiments, at least one selected from R¹ in Formula 1, R² in Formula 2, and R³ in Formula 3 may be a hydrophobic group that is different from others of R¹ to R³. For example, R¹ in Formula 1 may be a different hydrophobic group from R² in Formula 2, and R³ in Formula 3. For example, R¹ in Formula 1, R² in Formula 2, and R³ in Formula 3 may each be different hydrophobic groups. In some embodiments, R¹ in Formula 1 may be a hydrogen atom, and R² in Formula 2, and R³ in Formula 3 may be the same hydrophobic group.

According to an embodiment, the hydrophobic moiety may be represented by Formula 4 below. For example, in some embodiments R¹ in Formula 1 may be represented by Formula 4.

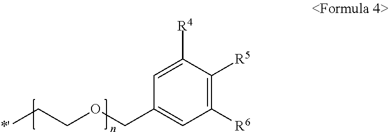

In Formula 4, n is an integer of 3 to 6, R⁴, R⁵, and R⁶ are each independently hydrogen or a C1 to C4 alkyl group, and *′ is a bonding site. In some embodiments, at least one among R⁴, R⁵, and R⁶ may be a C1 to C4 alkyl group. For example, in some embodiments, at least one of R⁴ to R⁶ is a C3 to C4 branched chain alkyl group.

In some embodiments, at least one selected from R⁴, R⁵, and R⁶ may be an isopropyl group or a tert-butyl group. In some embodiments, R⁴ and R⁶ may be hydrogens, and R⁶ may be an isopropyl group, or a tert-butyl group. The hydrophobic moiety includes a branched chain alkyl group having a relatively small number of carbons, and thus may prevent a decrease in dispersion stability of the surfactant while preventing silicon particles scattering during the wafer dicing process from sticking to the wafer. In addition, the hydrophobic moiety of the surfactant according to an embodiment may be formed with relatively short chains, and thus may have an increased cleansing power against the organic containment may without leaving any residue on a top surface of the wafer due to aggregation.

For example, in some embodiments R¹ in Formula 1 may be represented by Formula 4.

In some embodiments, the surfactant may contain or may be a compound represented by Formula 5 below.

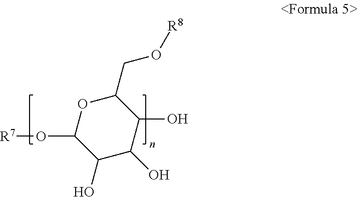

In Formula 5, n is 1 or 2, R⁷ and R⁸ are each independently a C6 to C12 polypropylene glycol group, substituted with alkyl benzyl group. In some embodiments, the alkyl benzyl group may include a benzyl group in which a hydrogen atom of a benzene ring is substituted with a C3 and C4 branched chain alkyl group.

In some embodiments, in Formula 5, R⁷ and R⁸ may be each independently a group represented by Formula 4.

In some embodiments, R⁷ and R⁸ are each independently a triethylene glycol group substituted with an alkyl benzyl group, a tetraethylene glycol group substituted with an alkyl benzyl group, a pentaethylene glycol group substituted with an alkyl benzyl group, or a hexaethylene glycol group substituted with an alkyl benzyl group.

In some embodiments, the alkyl group of the alkyl benzyl group is an isopropyl group or a tert-butyl group, linked to a carbon at a para position of a benzene ring, or is an isopropyl group or a tert-butyl group, linked to a carbon at a meta position of a benzene ring.

In some embodiments, the surfactant may include a compound represented by Formula 6-1 to Formula 6-4 below.

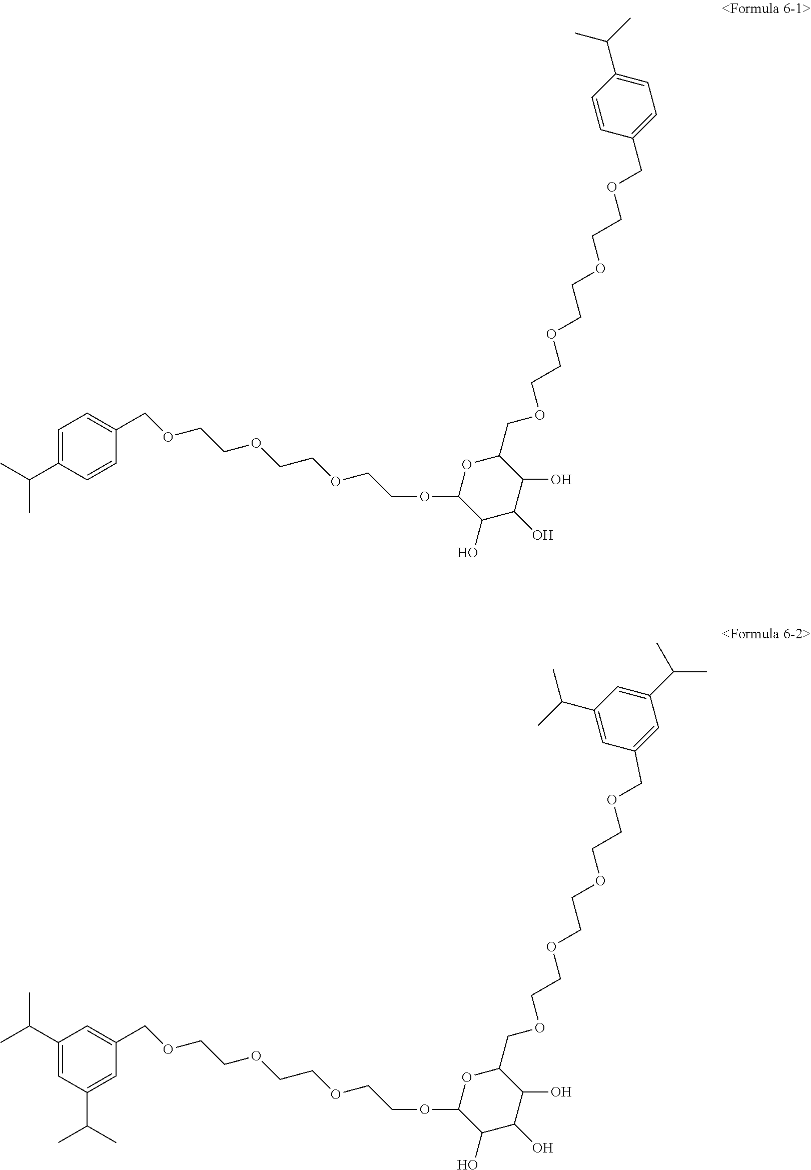 [SMILES: CC(C)c1ccc(COCCOCCOCCOCC2OC(OCCOCCOCCOCc3ccc(C(C)C)cc3)C(O)C(O)C2O)cc1 ; CC(C)c1cc(COCCOCCOCCOCC2OC(OCCOCCOCCOCc3cc(C(C)C)cc(C(C)C)c3)C(O)C(O)C2O)cc(C(C)C)c1]

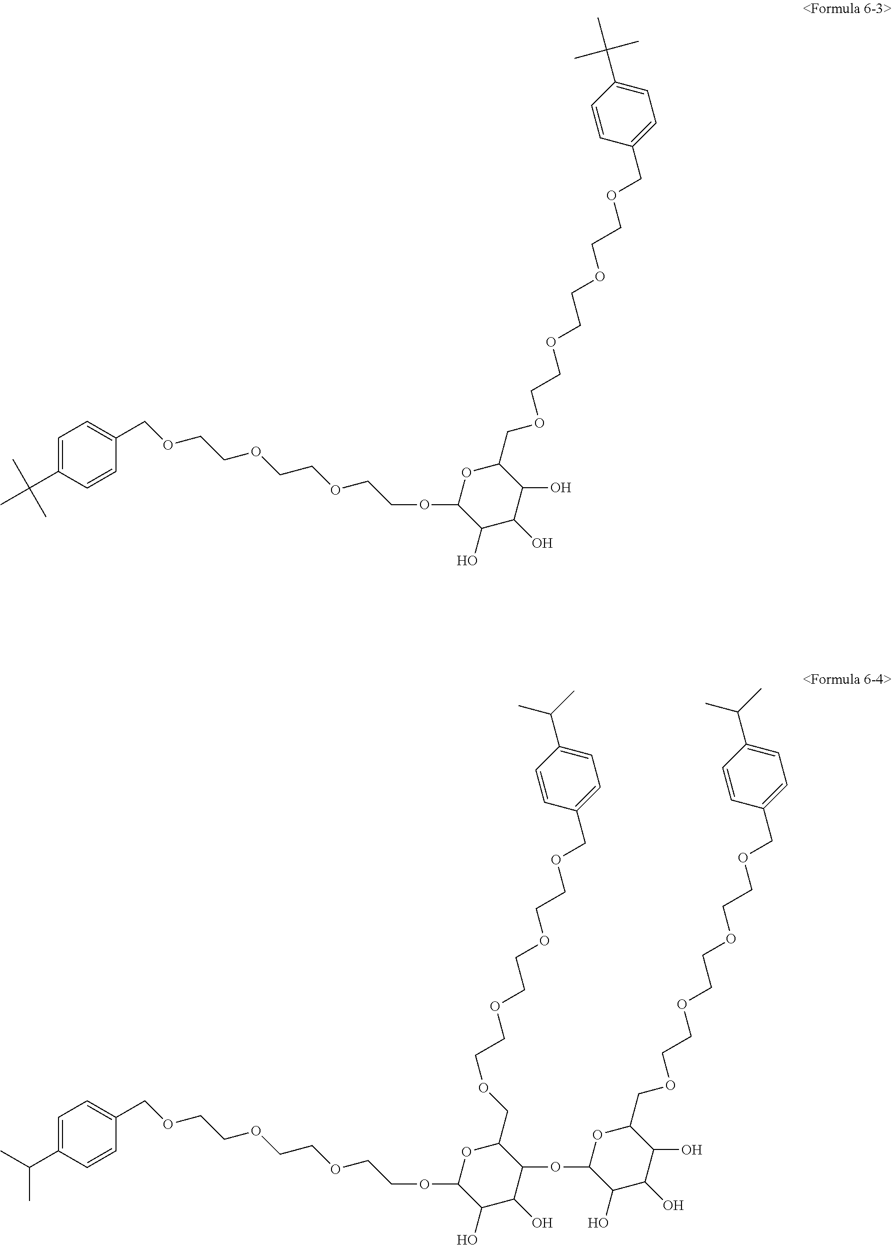 [SMILES: CC(C)(C)c1ccc(COCCOCCOCCOCC2OC(OCCOCCOCCOCc3ccc(C(C)(C)C)cc3)C(O)C(O)C2O)cc1 ; CC(C)c1ccc(COCCOCCOCCOCC2OC(OC3C(COCCOCCOCCOCc4ccc(C(C)C)cc4)OC(OCCOCCOCCOCc4ccc(C(C)C)cc4)C(O)C3O)C(O)C(O)C2O)cc1]

In some embodiments, the surfactant may include a compound represented by Formula 7 below.

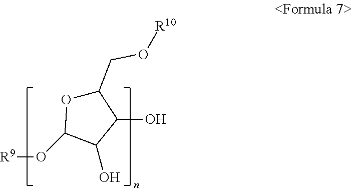

In Formula 7, n is 1 or 2, R⁹ and R¹⁰ are each independently a C6 to C12 polypropylene glycol group, substituted with alkyl benzyl group. In some embodiments, the alkyl benzyl group may be a benzyl group in which a hydrogen atom of a benzene ring is substituted with a C3 and C4 branched chain alkyl group.

In some embodiments, in Formula 7, R⁹ and R¹⁰ may be each independently represented by Formula 4.

In some embodiments, the surfactant may include a compound represented by Formula 8-1 to Formula 8-4 below.

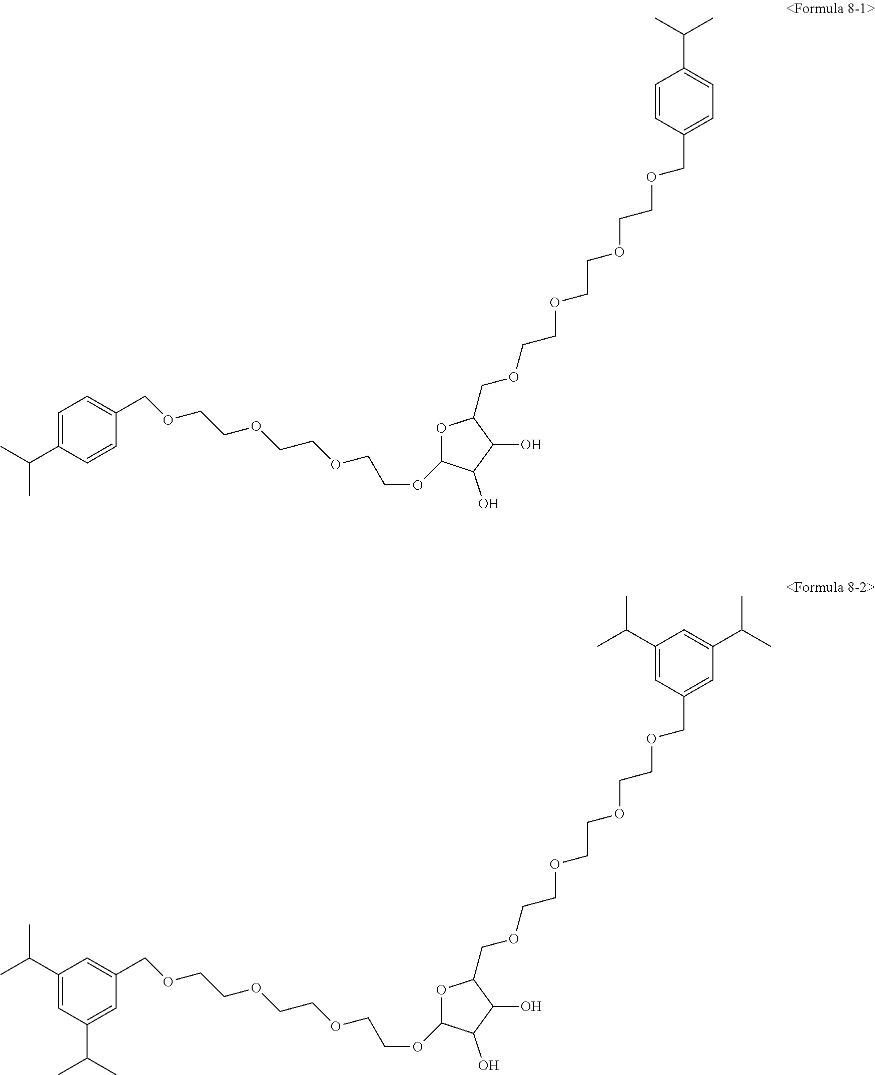

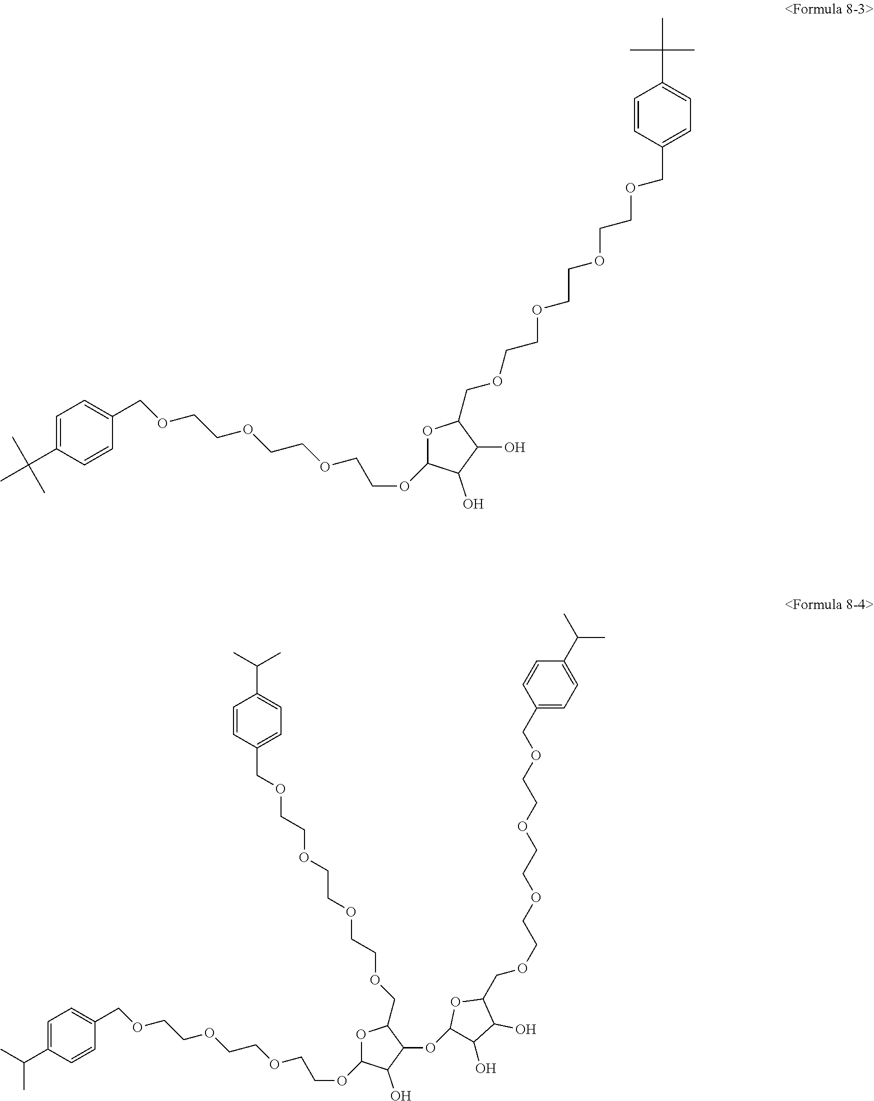

In some embodiments, the surfactant may include a compound represented by Formula 9 below.

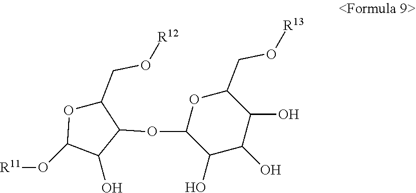

In Formula 9, R¹¹, R¹², and R¹³ are each independently a C6 to C12 polypropylene glycol group, substituted with alkyl benzyl group. In some embodiments, the alkyl benzyl group may be a benzyl group in which a hydrogen atom of a benzene ring is substituted with a C3 and C4 branched chain alkyl group. In some embodiments, in Formula 7, R⁹ and R¹⁰ may be each independently represented by Formula 4.

In some embodiments, a content of the surfactant among the total weight of the cleansing composition for wafer dicing may be in a range of about 0.0001 wt % to about 20 wt %. However, embodiments of the present inventive concept are not necessarily limited to the above-described range.

In some embodiments, a weight average molecular weight of the surfactant may be less than about 3,000 g/mol. In some embodiments, a weight average molecular weight of the surfactant may be in a range of about 400 g/mol to about 2,500 g/mol. The surfactant of the cleansing composition for wafer dicing according to an embodiment has a relatively low molecular weight and includes a hydrophobic moiety having a relatively short length of the chain. Therefore, the surfactant may be prevented from leaving a residue on the surface of the wafer due to aggregation and may achieve increased cleansing power even with a relatively small amount.

According to an embodiment, the solvent included in the cleansing composition for wafer dicing may include a protic solvent. The protic solvent may interact with a hydrophilic moiety of the surfactant, which may increase the dispersion stability of the surfactant. In some embodiments, the hydrophilic moiety of the surfactant may include a non-ionic hydrophilic group. The surfactant is stably dissolved in a protic solvent, and thus the cleansing composition for wafer dicing may have an increased cleansing power.

In some embodiments, the protic solvent may include water, a protic organic solvent, or a combination thereof. The protic organic solvent may include: an alcohol-based solvent such as methanol, ethanol, n-propanol, i-propanol, n-butanol, i-butanol, sec-butanol, t-butanol, n-pentanol, i-pentanol, 2-methyl butanol, sec-pentanol, t-pentanol, 3-methoxy butanol, n-hexanol, 2-methyl pentanol, sec-hexanol, 2-ethyl butanol, sec-heptanol, n-octanol, 2-ethyl hexanol, sec-octanol, n-nonyl alcohol, n-decanol, sec-undecyl alcohol, trimethyl nonyl alcohol, sec-tetradecyl alcohol, sec-heptadecyl alcohol, cyclohexanol, methyl cyclohexanol, benzyl alcohol, ethylene glycol, 1,2-propylene glycol, 1,3-butylene glycol, diethylene glycol, dipropylene glycol, triethylene glycol, tripropylene glycol; an ether-based solvent such as ethylene glycol methyl ether, ethylene glycolether ether, ethylene glycol monophenyl ether, diethylene glycol monomethyl ether, diethylene glycol monoethyl ether, diethylene glycol mono-n-butyl ether, diethylene glycol mono-n-hexyl ether, ethoxy triglycol, tetraethylene glycol mono-n-butyl ether, propylene glycol monomethyl ether, propylene glycol propyl ether, dipropylene glycol monomethyl ether, dipropylene glycol monoethyl ether, and tripropylene glycol monomethyl ether; an ester-based solvent such as methyl lactate, ethyl lactate, n-butyl lactate, and n-amyl lactate; and a combination thereof.

In some embodiments, a content of the solvent among the total weight of the cleansing composition for wafer dicing may be in a range of about 99.9999 wt % to about 80 wt %. However, embodiments of the present inventive concept are not necessarily limited to the above-described range.

In some embodiments, the cleansing composition for wafer dicing may further include an additive. The additive may interact with the surfactant and thus may induce dissolution and dispersion of the surfactant. In an embodiment, the additive may include at least one compound selected from monosaccharides, disaccharides, and a derivative thereof. In some embodiments in which the protic organic solvent was included as a solvent, the cleansing composition may further include the additive, and thus residue of the surfactant on the wafer surface may decrease in the protic organic solvent. The specific types of monosaccharides, disaccharides, and a derivative thereof may be similar to the descriptions of the hydrophilic moiety of the surfactant.

In some embodiments, the content of the additive among the total weight of the cleansing composition for wafer dicing may be in a range of about 0.00001 wt % to about 5 wt %. However, embodiments of the present inventive concept are not necessarily limited to the above-described range.

The cleansing composition for wafer dicing according to an embodiment may include a surfactant, which includes a hydrophilic moiety and at least one hydrophobic moiety, and a solvent. In an embodiment, the hydrophilic moiety may be selected from monosaccharides, disaccharides, or derivatives thereof, and the hydrophobic moiety may include a C4 to C20 polyethylene glycol group, substituted with an alkyl benzyl group. The surfactant may have a relatively low molecular weight and a non-ionic single molecule having a chemical structure that includes a hydrophilic head and at least one hydrophobic leg. In addition, the hydrophobic leg may be composed of a polyether group having a relatively short chain and may include an alkyl benzyl group at the end. Therefore, since hydrophobicity and hydrophilicity are balanced within the surfactant molecule, a phenomenon of self-aggregation or a random coil of the hydrophobic leg may be reduced, and aggregation with another adjacent hydrophobic leg may be reduced. Therefore, residue formed due to the phenomenon of aggregation, or a random coil may be prevented from remaining on the wafer surface, and a sticking phenomenon of wafer particles scattering during the wafer dicing process to the particle may decrease.

In a wafer back grinding process, which is performed before the wafer dicing process, a lamination tape is attached to the top surface of the wafer to protect the wafer, and the lamination tape is removed after the back grinding process. During the following wafer dicing process, the composition according to an embodiment of the present inventive concept may be used, the surfactant of the composition may include an alkyl benzyl group at the end of the hydrophobic moiety, and thus a lamination tape residue left on the wafer surface may be more easily removed.

Hereinafter, to aid understanding of the present inventive concept, synthesis examples of specific surfactants will be described. However, embodiments of the present inventive concept are not necessarily limited to the following synthesis examples.

### Synthesis Example: Manufacture of Surfactant (Formula 6-1)

### (1) Manufacturing Example 1: Manufacture of Reactant A

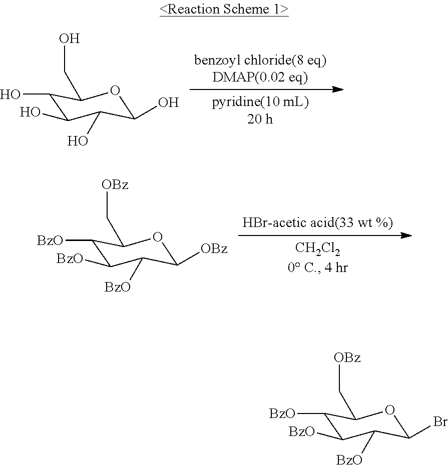

Referring to Reaction Scheme 1,270 mg (1.5 mmol) (1 eq) of beta-d-glucose (β-D-glucose) was added to 10 mL of a pyridine solution, in which 1.4 mL (12 mmol) (8 eq) of benzoyl chloride and 3.66 mg (0.03 mmol) (0.02 eq) of 4-dimethyl aminopyridine (DMAP) were added, and the mixture was stirred for 20 hours at room temperature.

Thereafter, 1 mL of hydrogen bromide (33 wt % in acetic acid solution) and 5 mL of dichloromethane were added to the produced solution and stirred at 0° C. for four hours. Then, the produced solution was subjected to extraction once with methylene chloride (MC):saturated sodium bicarbonate (saturated NaHCO₃) and twice with MC:sodium chloride (NaCl (brine)), then moisture in the extract was removed with sodium sulfate (Na₂SO₄), and the resultant was filtered. Then, the product thus obtained was purified by column chromatography to obtain 770 mg of Reactant A represented by Formula 10 below (yield of 78%).

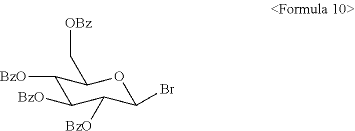

### (1) Manufacturing Example 2: Manufacture of Reactant B

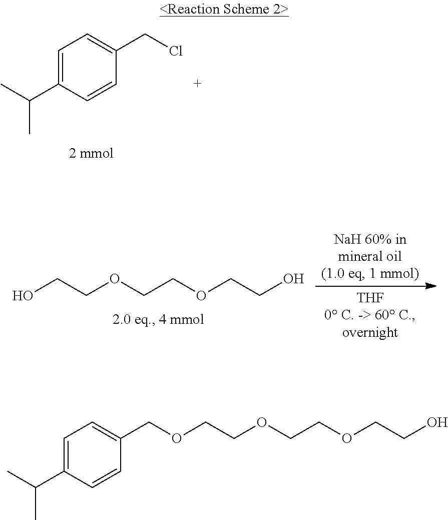 [SMILES: CC(C)c1ccc(CCl)cc1 ; OCCOCCOCCO ; CC(C)c1ccc(COCCOCCOCCO)cc1]

Referring to Reaction Scheme 2, 337.32 mg (2 mmol) (1 eq) of 1-(chloromethyl)-4-isopropylbenzene, 536 mL (4 mmol) (2 eq) of triethylene glycol were reacted in a solution with 80 mg (2 mmol) (1 eq) of sodium hydride (NaH) (60 wt % in mineral oil) and 10 mL of tetrahydrofuran (THF) at 0° C. for 10 minutes, and then was reacted at 60° C. for 12 hours (e.g., overnight). Then, the reaction solution was quenched with ice water, extraction was performed with MC:H₂O, then the moisture in the extract was removed over magnesium sulfate (MgSO₄), and the resultant was filtered. Then the product thus obtained was purified by column chromatography to obtain Reactant B 492 mg represented by Formula 11 below (yield of 86%).

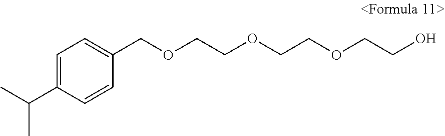 [SMILES: CC(C)c1ccc(COCCOCCOCCO)cc1]

### (3) Manufacture of Surfactant (Formula 6-1)

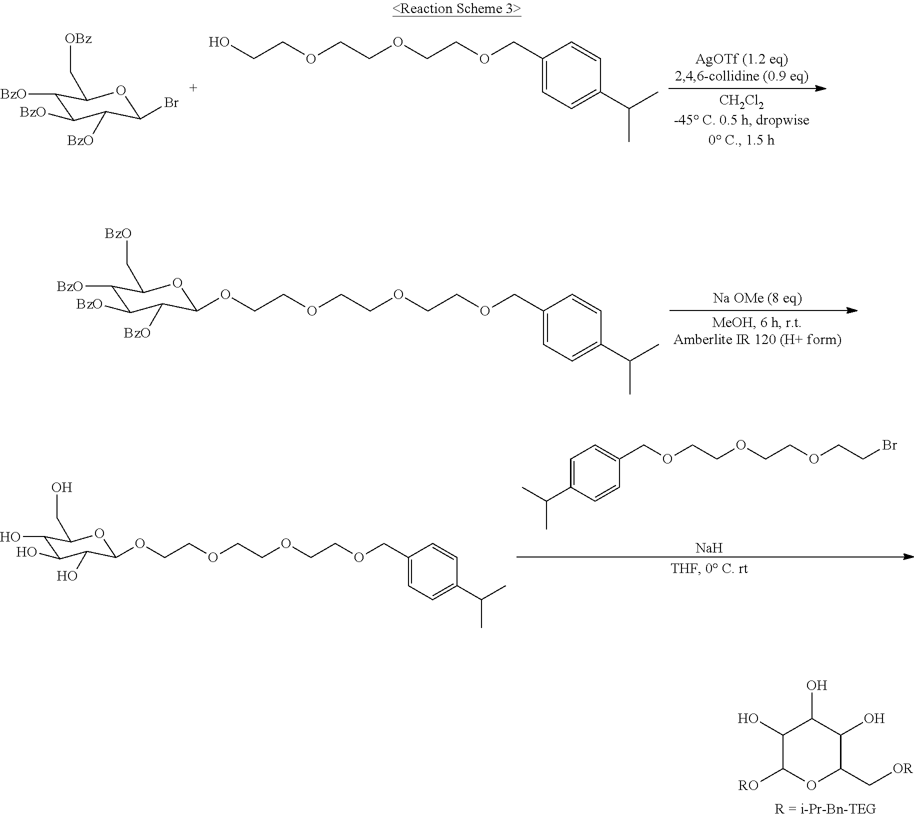

Referring to Reaction Scheme 3, Reactant A of 666 mg (1 mmol (1 eq) and Reactant B of 315 mg (1.1 mmol) (1.1 eq) were added to 5 mL of dichloromethane solution with 308 mg (1.2 mmol)(1.2 eq) of silver trifluoromethanesulfonate and 109 mg (0.9 mmol)(0.9 eq) of 2,4,6-trimethylpyridine, the mixture was reacted at −45° C. for 30 minutes with a dropwise, and then was stirred at 0° C. for 1.5 hours. Then, 0.2 mL of pyridine was added to quench the reaction, the resultant was filtered through a celite pad to remove a byproduct, then washed sequentially with 1 M of sodium thiosulfate (Na₂S₂O₃) aqueous solution, 0.1 M of hydrochloric acid (HCl) aqueous solution, brine (NaCl), and dried and filtered with Na₂SO₄ to obtain a first intermediate product.

Then, the first intermediate product was added to 5 mL of methanol with 0.91 mL (4 mmol) (8 eq) of sodium methoxide, and the mixture was reacted at room temperature (25° C.) for 6 hours. Then, a cation resin (Amberite IR-120 Resin(H+form)) was added and stirred for 30 minutes, then was filtered through a celite pad, and then was purified by column chromatography to obtain a second intermediate product.

Next, the second intermediate product was reacted with 112 mg (0.32 mmol)(0.9 eq) of 1-((2-(2-(2-bromomethoxy)ethoxy)methyl)-4-isopropyl benzene, 14.4 mg (0.36 mmol)(1 eq) of sodium hydride, and 2 mL of tetrahydrofuran (THF) at 0° C. for 10 minutes, and then was reacted at room temperature (25° C.) for 12 hours. Then, the reaction solution was quenched with ice water, then extraction was performed with MC:H₂O, the moisture in the extract was removed over MgSO₄, and the resultant was filtered. Then, the product thus obtained was purified by column chromatography to obtain a compound represented by Formula 6-1 of 255.2 mg (yield of 86%, weight average molecular weight of 708.88 g/mol).

Hitherto, non-limiting embodiments of the present inventive concept has been described in detail. However, embodiments of the present inventive concept are not necessarily limited to the described embodiments, and various modifications and changes may be made by those skilled in the art within the technical spirit and scope of the present inventive concept.

While the present inventive concept has been particularly shown and described with reference to non-limiting embodiments thereof, it will be understood that various changes in form and details may be made therein without departing from the spirit and scope of the present inventive concept.

What is claimed is:

1. A cleansing composition for wafer dicing, comprising:
a surfactant including a hydrophilic moiety and a hydrophobic moiety; and
a solvent,
wherein the hydrophilic moiety is selected from monosaccharides, disaccharides, or derivatives thereof, and
the hydrophobic moiety includes a C4 to C20 polyethylene glycol group substituted with an alkyl benzyl group.

2. The cleansing composition of claim 1, wherein the monosaccharides include a five-membered furanose ring or a six-membered pyranose ring.

3. The cleansing composition of claim 1, wherein the hydrophilic moiety includes at least one non-ionic hydrophilic group selected from a hydroxy group, an amine oxide group, a phosphine oxide group, and a sulfur oxide group.

4. The cleansing composition of claim 1, wherein the cleansing composition includes a plurality of the hydrophobic moiety.

5. The cleansing composition of claim 1, wherein the surfactant is represented by Formula 1 below:
R¹—X—Y¹ <Formula 1>
wherein, in Formula 1, R¹ is a C4 to C20 polyethylene glycol group substituted with an alkyl benzyl group,
X is a structural unit including at least one selected from a structural unit of Formula 2 below and a structural unit of Formula 3 below, and
Y¹ is a hydrophilic group; 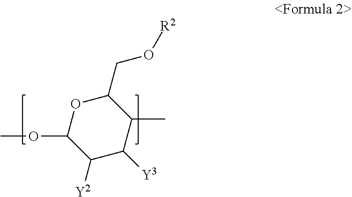
wherein, in Formula 2, R² is hydrogen, or a C4 to C20 polyethylene glycol group substituted with an alkyl benzyl group, and
Y² and Y³ are each independently a hydrophilic group; 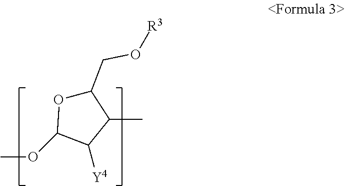
wherein, in Formula 3, R³ is hydrogen or a C4 to C20 polyethylene glycol group substituted with an alkyl benzyl group, and
Y⁴ is a hydrophilic group.

6. The cleansing composition of claim 1, wherein the hydrophobic moiety is a group represented by Formula 4 below: 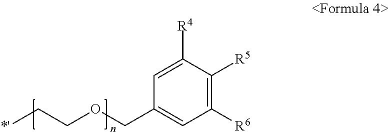
wherein, in Formula 4, n is an integer of 3 to 6,
R⁴, R⁵, and R⁶ are each independently hydrogen or a C1 to C4 alkyl group, and
*′ is a bonding site.

7. The cleansing composition of claim 6, wherein, in Formula 4, at least one of R⁴, R⁵, and R⁶ is a C3 to C4 branched chain alkyl group.

8. The cleansing composition of claim 1, wherein the solvent includes at least one composition selected from water and a protic organic solvent.

9. The cleansing composition of claim 8, wherein:
the solvent includes the protic organic solvent; and
the composition further comprises an additive including a monosaccharide.

10. The cleansing composition of claim 1, wherein a weight average molecular weight of the surfactant is in a range of about 400 g/mol to about 2,500 g/mol.

11. A cleansing composition for wafer dicing, comprising:
a surfactant represented by Formula 1 below; and
a solvent
R¹—X—Y¹ <Formula 1>
wherein, in Formula 1, X is a monosaccharide, a disaccharide, or a derivative thereof,
R¹ is a C4 to C20 polyether group substituted with an alkyl benzyl group, and
Y¹ is a non-ionic hydrophilic group.

12. The cleansing composition of claim 11, wherein an alkyl group of the alkyl benzyl group is bonded to carbon at a para position or carbon at a meta position of the benzene ring.

13. The cleansing composition of claim 12, wherein the alkyl group of the alkyl benzyl group is an isopropyl group or a tert-butyl group.

14. The cleansing composition of claim 11, wherein R¹ is represented by Formula 4 below: 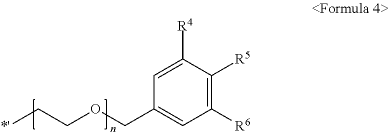
wherein, in Formula 4, n is an integer of 3 to 6,
R⁴, R⁵, and R⁶ are each independently hydrogen or a C1 to C4 alkyl group, wherein at least one of R⁴, R⁵, and R⁶ is a C1 to C4 alkyl group, and
*′ is a bonding site.

15. The cleansing composition of claim 11, wherein, in Formula 1, X includes at least one structural unit selected from Formula 2 below and Formula 3 below. 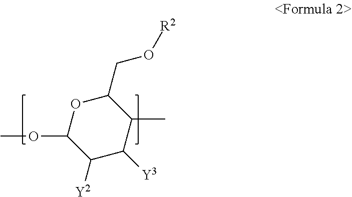
wherein, in Formula 2, R² is hydrogen or a C4 to C20 polyethylene glycol group substituted with an alkyl benzyl group, and
Y² and Y³ are each independently a non-ionic hydrophilic group; 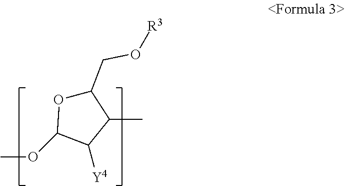
wherein, in Formula 3, R³ is hydrogen or a C4 to C20 polyethylene glycol group substituted with an alkyl benzyl group, and
Y⁴ is a non-ionic hydrophilic group.

16. The cleansing composition of claim 15, wherein Y² and Y³ in Formula 2 and Y⁴ in Formula 3 are each a hydroxy group.

17. The cleansing composition of claim 11, wherein a weight average molecular weight of the surfactant is in a range of about 400 g/mol to about 2,500 g/mol.

18. A cleansing composition for wafer dicing, comprising:
a surfactant represented by Formula 5 below; and
water: 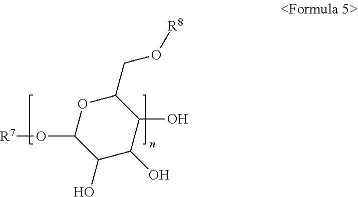
wherein, in Formula 5, n is 1 or 2, R⁷ and R⁸ are each independently a C6 to C12 polypropylene glycol group substituted with an alkyl benzyl group.

19. The cleansing composition of claim 18, wherein, in Formula 5, R⁷ and R⁸ are each independently a triethylene glycol group substituted with an alkyl benzyl group, a tetraethylene glycol group substituted with an alkyl benzyl group, a pentaethylene glycol group substituted with an alkyl benzyl group, or a hexaethylene glycol group substituted with an alkyl benzyl group.

20. The cleansing composition of claim 18, wherein an alkyl group of the alkyl benzyl group is an isopropyl group or a tert-butyl group, linked to a carbon at a para position of a benzene ring, or is an isopropyl group or a tert-butyl group, linked to a carbon at a meta position of a benzene ring.
